(19) United States
(12) Patent Application Publication
(10) Pub. No.: US 2026/0339215 A1
(43) Pub. Date: Oct. 29, 2026

(54) APPARATUS AND METHOD FOR SPIN COATING

(71) Applicant: NANYA TECHNOLOGY CORPORATION, New Taipei City (TW)

(72) Inventor: Jung Tzu PENG, New Taipei City (TW)

(21) Appl. No.: 19/192,358

(22) Filed: Apr. 29, 2025

(51) Int. Cl. G03F 7/16; H10N 10/17

(52) U.S. Cl. CPC G03F 7/162; H10N 10/17

(57) ABSTRACT

A spin coating apparatus includes a first chuck, a circular thermoelectric unit, a motor and a main controller. The circular thermoelectric unit is spaced from and disposed surrounding the first chuck, wherein the circular thermoelectric unit includes an n-type semiconductor and a p-type semiconductor electrically connected to the n-type semiconductor. The motor is connected to the circular thermoelectric unit and the first chuck. The main controller is electrically connected to the circular thermoelectric unit and the motor.

### BACKGROUND

### FIELD OF INVENTION

The present disclosure relates to a spin coating apparatus. More particularly, the present disclosure relates to a spin coating apparatus including a thermoelectric unit operated by Peltier effect and a method for the spin coating.

### Description of Related Art

In the spin coating process, photoresist distributed unevenly at an edge portion of a substrate may cause uniformity problems, such as edge bead. The edge bead is formed depend on various factors, such as the properties of the fluid, the parameter of the spin coating, the environment of the spin coating and the properties of the substrate.

The formation of the edge bead may cause the feature pattern of an edge portion of the substrate become incomplete after the exposure process, resulting in defect problem occurred at the edge portion of the substrate. Thus, the improvement of uniformity of the photoresist is crucial during the spin coating process.

### SUMMARY

The disclosure provides a spin coating apparatus. The spin coating apparatus includes a first chuck, a circular thermoelectric unit, a motor and a main controller. The circular thermoelectric unit is spaced from and disposed surrounding the first chuck, wherein the circular thermoelectric unit includes an n-type semiconductor and a p-type semiconductor electrically connected to the n-type semiconductor. The motor is connected to the circular thermoelectric unit and the first chuck. The main controller is electrically connected to the circular thermoelectric unit and the motor.

The disclosure provides a method. The method includes fixing a substrate with a first chuck, rotating the substrate with a motor through the first chuck, wherein the motor is connected to the first chuck. The method further includes adjusting a temperature of a circular thermoelectric unit to control temperature of an edge portion of the substrate during spin coating process, wherein the circular thermoelectric unit directly contacts the edge portion of the substrate, and wherein the circular thermoelectric unit is connected to the motor and rotated simultaneously with the substrate.

These and other features, aspects, and advantages of the present disclosure will become better understood with reference to the following description and appended claims.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a cross-section view of a spin coating apparatus according to some embodiments of the present disclosure.

FIG. 2 is a cross-section view of a spin coating apparatus according to different embodiment of the present disclosure.

FIG. 3 is a flow chart of a method of controlling a temperature of an edge portion of a substrate during a spin coating process according to some embodiments of the present disclosure.

FIG. 4 is a top view of a spin coating apparatus during the spin coating process according to some embodiments of the present disclosure.

FIG. 5 is a cross-section view of a spin coating apparatus during the spin coating process according to some embodiments of the present disclosure.

FIG. 6 is a cross-section view of a spin coating apparatus after the spin coating process according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

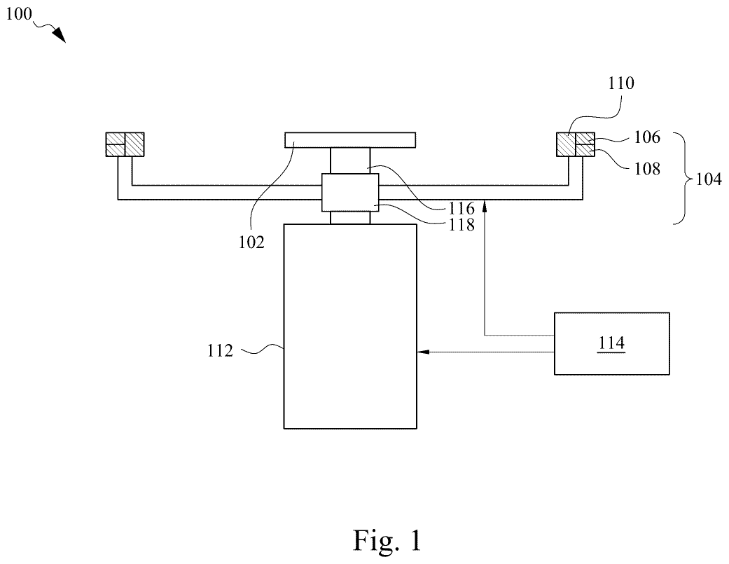

Referring to FIG. 1, a spin coating apparatus 100 is illustrated. The spin coating apparatus 100 includes a first chuck 102, a circular thermoelectric unit 104, a motor 112 and a main controller 114. The circular thermoelectric unit 104 is spaced from the first chuck 102 and disposed surrounding the first chuck 102. The motor 112 is connected to the first chuck 102 and the circular thermoelectric unit 104. The main controller 114 is electrically connected to the circular thermoelectric unit 104 and the motor 112. In some embodiments, a top surface of the circular thermoelectric unit 104 may be level with a top surface of the first chuck 102.

The first chuck 102 is configured to support a substrate (as following described). The circular thermoelectric unit 104 is configured to control a temperature of an edge portion of the substrate. The motor 112 is configured to control dynamic motion (e.g., velocity and acceleration of the rotation) of the first chuck 102 and the circular thermoelectric unit 104. The main controller 114 is configured to setup the parameter of the circular thermoelectric unit 104 and the motor 112 depend on the requirement of the process, such as rotation speed of the motor 112 and the magnitude of direct current applied to the circular thermoelectric unit 104.

Specifically, the spin coating apparatus 100 further comprises a rotating shaft 116 and a cylinder sleeve 118 surrounding the rotating shaft 116. The motor 112 is connected to the first chuck 102 through the rotating shaft 116, and is connected to the circular thermoelectric unit 104 through the cylinder sleeve 118. Therefore, the first chuck 102 is rotated with the motor 112 through the rotating shaft 116. The circular thermoelectric unit 104 is rotated and moved up and down with the motor 112 through the cylinder sleeve 118. The cylinder sleeve 118 may move the circular thermoelectric unit 104 up and down relative to the first chuck 102. In some embodiments, the motor 112 can rotate the first chuck 102 and the circular thermoelectric unit 104 simultaneously through the rotating shaft 116 and the cylinder sleeve 118 respectively. In some embodiments, the rotation speed of the first chuck 102 and the circular thermoelectric unit 104 may be the same.

In some embodiments, the circular thermoelectric unit 104 is a thermoelectric unit operated by Peltier effect, which may adjust temperature, such as achieving cooling and heating effects, by applying direct current. The circular thermoelectric unit 104 may be formed by any suitable semiconductor material, such as bismuth telluride, antimony telluride and bismuth selenide pair. The circular thermoelectric unit 104 includes a p-type semiconductor 106 and an n-type semiconductor 108 electrically connected to the p-type semiconductor 106. In some embodiments, the p-type semiconductor 106 may be disposed on the n-type semiconductor 108. When the direct current is applied to the circular thermoelectric unit 104, the current may flow from the n-type semiconductor 108 to the p-type semiconductor 106, making the circular thermoelectric unit 104 absorb heat to act as a cold portion. When the current may flow back from the p-type semiconductor 106 to the n-type semiconductor 108, making the circular thermoelectric unit 104 release heat to act as a hot portion. Thus, the circular thermoelectric unit 104 may adjust the temperature depend on the magnitude of the applied direct current.

In addition, the circular thermoelectric unit 104 may performed rapidly cooling and heating due to the faster migration of electrons, providing an effective temperature control during the spin coating process. In some embodiments, the temperature of the circular thermoelectric unit 104 may be adjusted in a range from 15 °C to 30 °C. In some embodiments, the temperature of the circular thermoelectric unit 104 may be further adjusted in an unit of 0.1 °C.

In some embodiments, the circular thermoelectric unit 104 may further include a second chuck 110. In some embodiments, the second chuck 110 may be a circular shape and disposed adjacent an inner sidewall of the p-type semiconductor 106 and the n-type semiconductor 108. In some embodiments, a top surface of the second chuck 110 is level with a top surface of the p-type semiconductor 106. In some embodiments, the second chuck 110 may be disposed in a recess (not shown) exposed on a top surface of the p-type semiconductor 106. In some embodiments, a width and a depth of the recess may be about 1 mm. The second chuck 110 is configured to support the edge portion of the substrate (as following described) without vibration during the spin coating process.

The main controller 114 is electrically connected to the motor 112 and the circular thermoelectric unit 104. For example, the main controller 114 may setup the rotation speed of the motor 112 depend on the requirement of the process, so that the first chuck 102 and the circular thermoelectric unit 104 may be rotated with the motor 112. In some embodiments, the rotation may be clockwise or counter-clockwise. In addition, the main controller 114 may setup the magnitude of the direct current applied to the circular thermoelectric unit 104, so that the temperature of the circular thermoelectric unit 104 may be adjusted to control the temperature of the edge portion of the substrate (as following described) during the spin coating process.

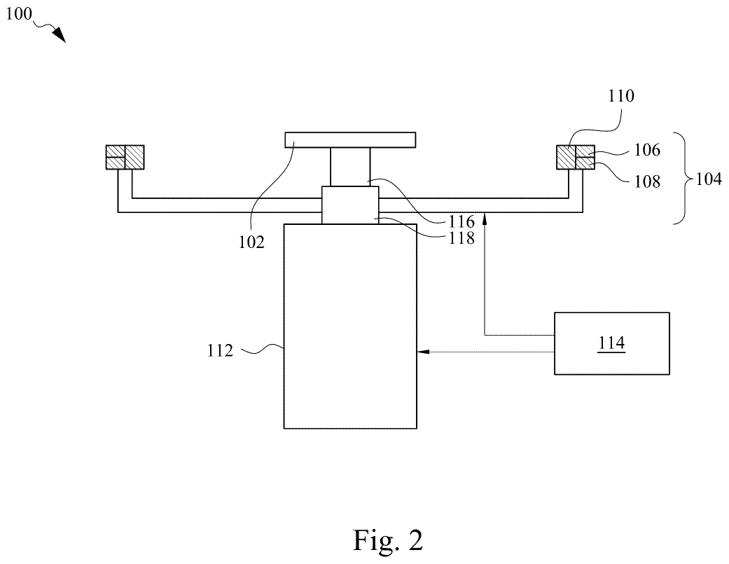

FIG. 2 is illustrated a cross-section view of different embodiment of the spin coating apparatus 100 of the present disclosure. The circular thermoelectric unit 104 is moved downwardly relative to the first chuck 102. The motion may be controlled by the parameter setting from the main controller 114. The motion of the circular thermoelectric unit 104 may be performed with the motor 112 through the cylinder sleeve 118. In other words, the cylinder sleeve 118 may move the circular thermoelectric unit 104 up and down relative to the first chuck 102. In some embodiments, the top surface of the circular thermoelectric unit 104 is lower than the top surface of the first chuck 102.

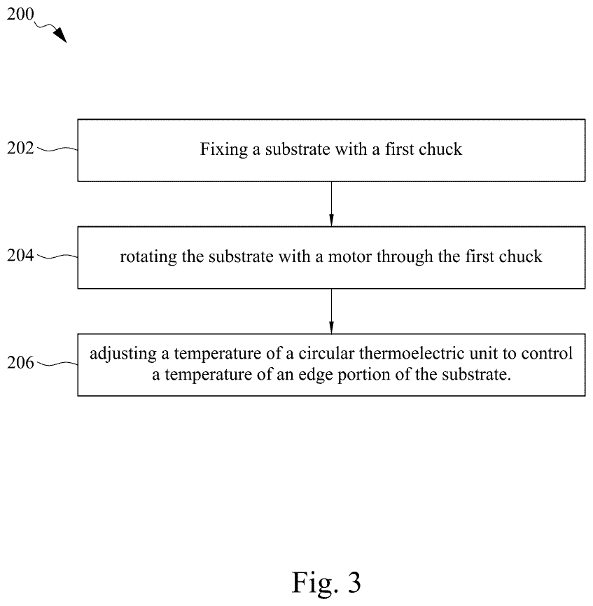

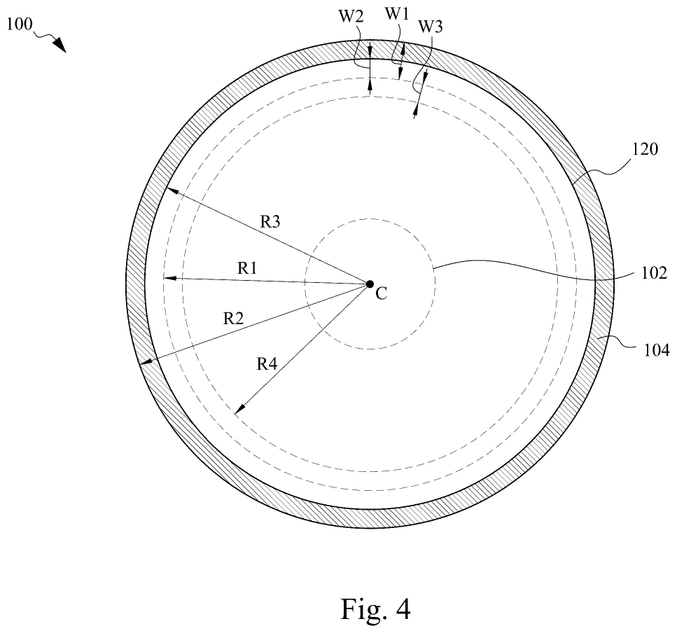

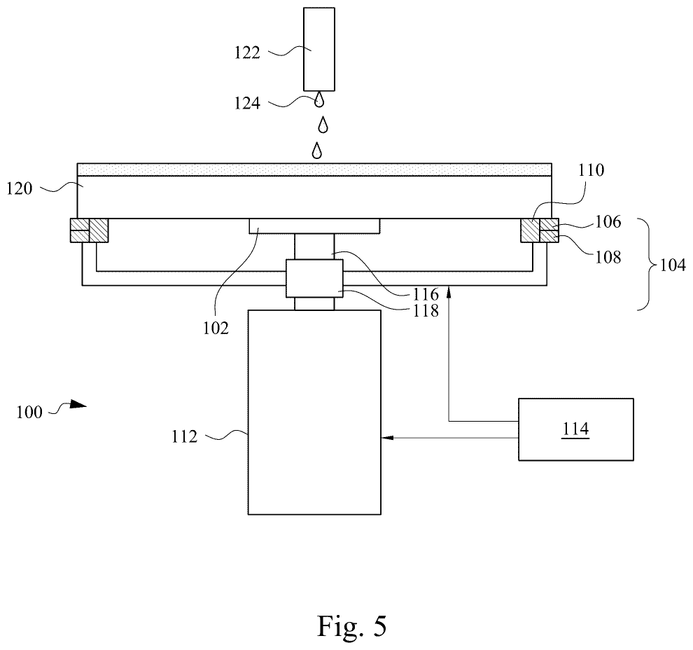

Refers to FIGS. 3-5, FIG. 3 is a flow chart of a method of controlling the temperature of the edge portion of the substrate during the spin coating process according to some embodiments of the present disclosure. FIG. 4 is illustrated a top view of the spin coating apparatus 100 during spin coating process according to some embodiments of the present disclosure. FIG. 5 is illustrated a cross-section view of the spin coating apparatus 100 during the spin coating process according to some embodiments of the present disclosure.

Referring to FIG. 3 and FIG. 4, the method begins from step 202. A substrate 120 is fixed with the first chuck 102. In some embodiments, the substrate 120 may be a semiconductor substrate. The substrate 120 is provided on the first chuck 102 and the circular thermoelectric unit 104 of the spin coating apparatus 100. In some embodiments, a center portion of the substrate 120 is disposed on the first chuck 102. In some embodiments, the first chuck 102 may be a vacuum chuck. The substrate 120 is fixed tightly through the first chuck 102, preventing from drifting during the spin coating process. In some embodiments, a top surface area of the first chuck 102 is smaller than a bottom surface area of the substrate 120.

Continuing, the circular thermoelectric unit 104 may comprise a center C, a radius R1 defined from an inner surface of the p-type semiconductor 106 and the n-type semiconductor 108 to the center C, and a radius R2 defined from an outer surface of the p-type semiconductor 106 and the n-type semiconductor 108 to the center C. A width W1 between the radius R1 and the radius R2 is in a range from 3 mm to 15 mm. The substrate 120 may be disposed concentrically on the circular thermoelectric unit 104. The substrate 120 may comprise a radius R3 between the radius R1 and the radius R2, so that the edge portion of the substrate 120 may be overlapped with the p-type semiconductor 106 and the n-type semiconductor 108 of the circular thermoelectric unit 104. The edge portion of the substrate 120 may include an overlapping width W2 to the p-type semiconductor 106 and the n-type semiconductor 108 of the circular thermoelectric unit 104. In some embodiments, the overlapping width W2 is in a range greater than 0 mm to 10 mm from an edge of the substrate 120. Since the radius R3 of the substrate 120 is between the radius R1 and the radius R2 of the circular thermoelectric unit 104, a portion of the p-type semiconductor 106 and the n-type semiconductor 108 of the circular thermoelectric unit 104 is protruding from a sidewall of substrate 120.

In some embodiments, the circular thermoelectric unit 104 may further comprise the second chuck 110 disposed adjacent the inner sidewall of the p-type semiconductor 106 and the n-type semiconductor 108. The circular thermoelectric unit 104 may comprise a radius R4 defined from an inner surface of the second chuck 110. A width W3 between the radius R1 and the radius R4 may be referred as a width of the second chuck 110, and the width W3 is in a range from 5 mm to 15 mm.

Referring to FIG. 3 and FIG. 5, the method goes to step 204. The substrate 120 is rotated with the motor 112 through the first chuck 102. During the spin coating process, a sprayer 122 is disposed above the substrate 120 and configured to apply a photoresist 124 to the substrate 120. The photoresist 124 is used to define feature patterns of the substrate 120 by following exposure process. The substrate 120 is rotated with the motor 112 through the first chuck 102 to distribute the photoresist 124 on the substrate 120, so that the photoresist 124 may cover an entire top surface of the substrate 120. In some embodiments, due to the circular thermoelectric unit 104 connected to the motor 112 through the cylinder sleeve 118, the rotation speed of the circular thermoelectric unit 104 and the substrate 120 may be the same during the spin coating process.

Referring to FIG. 3 and FIG. 5 continuing, the method goes to step 206. The temperature of the circular thermoelectric unit 104 is adjusted to control the temperature of the edge portion of the substrate 120. In some embodiments, the top surface of the circular thermoelectric unit 104 is level with the top surface of the first chuck 102 to directly contact the edge portion of the substrate 120. In some embodiments, the circular thermoelectric unit 104 still maintains directly contact the edge portion of the substrate 120 during the spin coating process. This configuration which the circular thermoelectric unit 104 is disposed below and directly contacts the edge portion of the substrate 120 during the spin coating process may make the circular thermoelectric unit 104 control the temperature of the edge portion of the substrate 120 by adjusting a temperature of the circular thermoelectric unit 104.

The main controller 114 may setup the parameter of the spin coating apparatus 100, such as the magnitude of the direct current applied to the circular thermoelectric unit 104. In some embodiments, the main controller 114 may adjust the magnitude of the direct current applied to the circular thermoelectric unit 104 to decrease the temperature of the circular thermoelectric unit 104. Since the circular thermoelectric unit 104 directly contacts the edge portion of the substrate 120 during the spin coating process, the temperature of the edge portion of the substrate 120 may be decreased through the circular thermoelectric unit 104, resulting in the temperature of the edge portion of the substrate 120 lower than a temperature of a center portion of the substrate 120. In some embodiments, a difference of the temperature between the edge portion of the substrate 120 and the center portion of the substrate 120 may be in a range from −2 °C to 2 °C

A temperature of the photoresist 124 in the pipe before spraying on the substrate 120 may be controlled in a specific temperature. Furthermore, temperature, humidity and flow rate of down force of process environment may be controlled as well. Therefore, a difference of the temperature between the photoresist 124 at the edge portion of the substrate 120 and the center portion of the substrate 120 may be comparable. Due to a difference of the temperature between the edge portion of the substrate 120 and the center portion of the substrate 120, it may vary an evaporation rate of the solvent of the photoresist 124 at the edge portion of the substrate 120 to change a thickness of the photoresist 124 at the edge portion of the substrate 120. In some embodiments, the temperature of the edge portion of the substrate 120 lower than the temperature of the center portion of the substrate 120 may decrease an evaporation rate of the solvent of the photoresist 124 while contacting the edge portion of the substrate 120, resulting in a lower viscosity while the photoresist 124 is at the edge portion of the substrate 120, further improving the distribution uniformity of the photoresist 124 and preventing from the likelihood of edge bead.

In addition, the main controller 114 may setup the parameter of the spin coating apparatus 100, such as the rotation speed of the motor 112. In some embodiments, the circular thermoelectric unit 104 may further comprise the second chuck 110 adjacent the inner sidewall of the p-type semiconductor 106 and the n-type semiconductor 108. In some embodiments, the second chuck 110 may be a vacuum chuck. The edge portion of the substrate 120 may be fixed tightly with the second chuck 110 of the circular thermoelectric unit 104 to prevent from vibration during the spin coating process, such that the rotation speed of the substrate 120 may be increased over 200 rpm to improve the distribution uniformity of the photoresist 124.

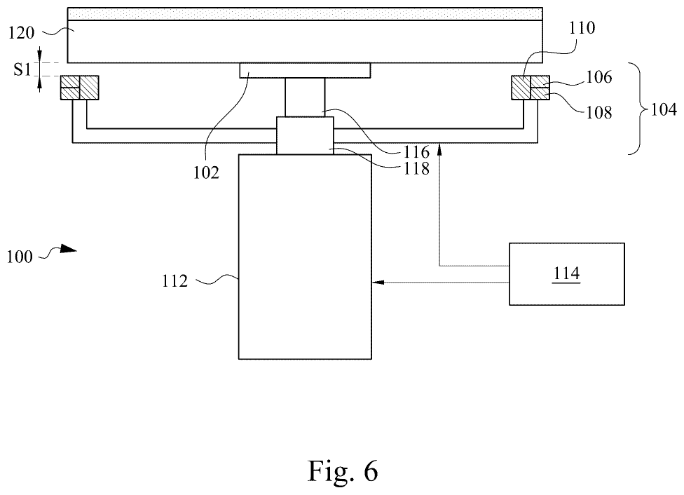

FIG. 6 is illustrated a cross-section view of the spin coating apparatus 100 after the spin coating process according to some embodiments of the present disclosure. After the spin coating process, the substrate 120 may be moved off the first chuck 102 with a robot arm (not shown). During the moving operation, the circular thermoelectric unit 104 moves downwardly relative to the first chuck 102 with the motor 112 to separate from the substrate 120, leaving a space S1 for the movement of the robot arm for preventing from blocking a transferring path of the robot arm.

The spin coating apparatus 100 of the present disclosure may include a first chuck 102, a circular thermoelectric unit 104 spaced from the first chuck 102 and disposed surrounding the first chuck 102, a motor 112 connected to the first chuck 102 and the circular thermoelectric unit 104 and a main controller 114 electrically connected to the circular thermoelectric unit 104 and the motor 112.

The spin coating apparatus 100 may control the temperature of the edge portion of the substrate 120 with the circular thermoelectric unit 104 operated by Peltier effect during the spin coating process. The circular thermoelectric unit 104 may vary the temperature depend on the magnitude of the applied direct current. The spin coating apparatus 100 may control the temperature of the edge portion of the substrate 120 lower than the temperature of the center portion of the substrate 120 to lower the evaporation rate of the solvent of the photoresist 124 at the edge portion of the substrate 120, thus improving the distribution uniformity of the photoresist 124 and minimizing the edge bead.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A spin coating apparatus, comprising:
a first chuck;
a circular thermoelectric unit spaced from and disposed surrounding the first chuck, wherein the circular thermoelectric unit comprises an n-type semiconductor and a p-type semiconductor electrically connected to the n-type semiconductor;
a motor connected to the circular thermoelectric unit and the first chuck; and
a main controller electrically connected to the circular thermoelectric unit and the motor.

2. The spin coating apparatus of claim 1, wherein the first chuck is configured to support a substrate; and wherein a top surface area of the first chuck is smaller than a bottom surface area of the substrate.

3. The spin coating apparatus of claim 2, wherein an edge portion of substrate has an overlapping width to the circular thermoelectric unit, and the overlapping width is in a range greater than 0 mm to 10 mm from an edge of the substrate.

4. The spin coating apparatus of claim 2, wherein a portion of the circular thermoelectric unit is protruding from a sidewall of substrate.

5. The spin coating apparatus of claim 1, wherein a top surface of the circular thermoelectric unit is level with a top surface of the first chuck.

6. The spin coating apparatus of claim 1, wherein a top surface of the circular thermoelectric unit is lower than a top surface of the first chuck.

7. The spin coating apparatus of claim 1, wherein the circular thermoelectric unit further comprises a second chuck.

8. The spin coating apparatus of claim 1, wherein a width of the circular thermoelectric unit is in a range from 3 mm to 15 mm.

9. The spin coating apparatus of claim 1, wherein the spin coating apparatus further comprises:
a cylinder sleeve connected to the motor and the circular thermoelectric unit; and
a rotating shaft connected to the motor and the first chuck.

10. A method, comprising:
fixing a substrate with a first chuck;
rotating the substrate with a motor through the first chuck, wherein the motor is connected to the first chuck; and
adjusting a temperature of a circular thermoelectric unit to control a temperature of an edge portion of the substrate during a spin coating process, wherein the circular thermoelectric unit directly contacts the edge portion of the substrate, and wherein the circular thermoelectric unit is connected to the motor, and a rotation speed of the circular thermoelectric unit and the substrate are the same.

11. The method of claim 10, wherein adjusting the temperature of the circular thermoelectric unit is operated by Peltier effect.

12. The method of claim 10, wherein the temperature of the circular thermoelectric unit is in a range from 15 °C to 30 °C.

13. The method of claim 10, wherein a difference of a temperature between the edge portion of the substrate and a center portion of the substrate is in a range from −2 °C to 2 °C.

14. The method of claim 10, wherein the circular thermoelectric unit further comprises a second chuck, wherein the edge portion of the substrate is fixed with the second chuck during the spin coating process.

15. The method of claim 10, wherein rotating the substrate with the motor through the first chuck comprises a rotation speed over 200 rpm.

16. The method of claim 10, wherein the circular thermoelectric unit moves downwardly to separate from the substrate after the spin coating process.
